(19) United States
(12) Patent Application Publication
(10) Pub. No.: US 2016/0014922 A1
(43) Pub. Date: Jan. 14, 2016

(54) ELECTRONIC DEVICE CASE WITH A COMBINATION CARD AND ITEM HOLDER

(71) Applicant: Fellowes, Inc., Itasca, IL (US)

(72) Inventors: Chinmoy BANERJEE, Schaumburg, IL (US); Harsh GANDHI, Carol Stream, IL (US); Richard KANG, Bloomingdale, IL (US)

(21) Appl. No.: 14/329,386

(22) Filed: Jul. 11, 2014

(51) Int. Cl. H05K 5/02; H05K 5/03; A45C 7/00; A45C 11/00; A45C 13/00

(52) U.S. Cl. CPC H05K 5/0286; A45C 11/00; A45C 13/002; A45C 7/0022; A45C 7/0031; H05K 5/03; A45C 2011/002; A45C 2011/001

(57) ABSTRACT

A case for use with an electronic device is provided. The case includes a case body and a moveable member. The case body has an opening for receiving the electronic device and a cavity. The moveable member is moveably connected to the case body and received in the cavity. The moveable member is configured to receive one or more articles or items on a surface thereof. The moveable member is moveable between (i) a first position stored in the cavity and (ii) a second position withdrawn from the cavity to present the one or more articles or items to a user for removal. At least a member operatively associated with the moveable member is configured to be flexible to enable the moveable member to deform in a first direction to receive one or more new articles or items on the surface of the moveable member.

### BACKGROUND

1. Field of the Invention

The present patent application relates to a case for use with a portable electronic device. More specifically, the present patent application relates to a case configured to store one or more articles or items along with the portable electronic device.

2. Description of Related Art

Many users tend to carry portable electronic devices, such as cellular phones and personal digital assistants (PDAs), for example, in addition to a carrying device for personal items (e.g., a wallet or clip). Such users tend to carry multiple items in their pockets, which can be bulky, inconvenient, and/or uncomfortable.

Some cases for portable electronic devices have storage for receiving and storing credit cards and other personal items therein. For example, a case for portable electronic device may include a side loading, built-in card slot in a rear portion thereof to receive one or more cards or folded bills. For example, a case for portable electronic device may include a back/rear compartment that holds one or more credit card(s) and/or ID's and a back/rear compartment door that opens to provide access to the credit card(s) or ID's stored in the back/rear compartment. For example, a case for portable electronic device may include a sliding drawer in a back/rear portion of the case that holds one or more credit card(s) and/or money bill(s) and that slides open to provide access to the credit card(s) and/or money bill(s) stored in the sliding drawer.

Some cases for portable electronic devices rely on a frictional interface between the one or more stored articles or items (e.g., cards) and the material of the case to keep the stored cards held therewithin. The frictional aspect of these cases may have undesirable effects when removing the stored cards; at times, the cards are difficult to remove from the case and the user may have to try more than once to remove the cards from the case. Among other things, the present patent application discloses improvements to cases for electronic devices.

### BRIEF SUMMARY

In one embodiment of the present patent application, a case for use with an electronic device is provided. The case includes a case body and a moveable member. The case body has a back wall and side walls extending therefrom forming an opening for receiving the electronic device and has a cavity provided in a rear portion thereof. The moveable member is moveably connected to the case body and received in the cavity. The moveable member and the rear portion of the case body are configured to form a storage space therebetween to receive one or more articles or items. The moveable member is moveable between (i) a first position stored in the cavity and (ii) a second position withdrawn from the cavity to present the one or more articles or items to a user for removal. At least one of the moveable member and the rear portion of the case body is configured to be flexible to increase the storage space and to receive one or more new articles or items in the storage space.

In another embodiment of the present patent application, a case for use with an electronic device is provided. The case includes a case body and a moveable member. The case body has a back wall and side walls extending therefrom forming an opening for receiving the electronic device and has a cavity provided in a rear portion thereof. The moveable member is moveably connected to the case body and received in the cavity. The moveable member is configured to receive one or more articles or items on a surface thereof. The moveable member is moveable between (i) a first position stored in the cavity and (ii) a second position withdrawn from the cavity to present the one or more articles or items to a user for removal. At least a member operatively associated with the moveable member is configured to be flexible to enable the moveable member to deform in a first direction to receive one or more new articles or items on the surface of the moveable member.

In yet another embodiment of the present patent application, a case for use with an electronic device is provided. The case includes a case body having a back wall and side walls extending therefrom forming an opening for receiving the electronic device. The case body has a storage space provided in a rear portion thereof for storing one or more articles or items therein. The case includes an actuator that is operatively associated with the case body. The movement of the actuator from a first position to a second position presents the stored articles or items, externally of the case body, so as to enable the user to remove the articles or items.

Other aspects, features, and advantages of the present invention will become apparent from the following detailed description, the accompanying drawings, and the appended claims.

### BRIEF DESCRIPTION OF THE DRAWINGS

Various embodiments are disclosed, by way of example only, with reference to the accompanying schematic drawings in which corresponding reference symbols indicate corresponding parts, in which

FIGS. 1 and 1A show top, perspective views of an exemplary case for use with an electronic device in accordance with an embodiment of the present patent application, where the case is in its first, closed or stored position in FIG. 1A and the case is in its second, open or in use position in FIG. 1;

FIGS. 2 and 2A show bottom, perspective views of the exemplary electronic device case in accordance with an embodiment of the present patent application, where the case is in its first, closed or stored position in FIG. 2A and the case is in its second, open or in use position in FIG. 2;

FIGS. 3 and 4 show side, cross-sectional views of the exemplary electronic device case with one or more articles or items stored therein, where the case is in its second, open or in use position, in accordance with an embodiment of the present patent application;

FIG. 3A shows a side, cross-sectional view of the exemplary electronic device case with one or more articles or items stored therein, where the case is in its first, closed or stored position, in accordance with an embodiment of the present patent application;

FIG. 5 shows another side, cross-sectional view of the exemplary electronic device case in which a through hole design is used to push the stored articles or items for removal in accordance with an embodiment of the present patent application;

FIG. 5A shows a partial, perspective view of the moveable member of the exemplary electronic device case in accordance with an embodiment of the present patent application;

FIG. 6 shows a front, perspective view of an exemplary case for use with an electronic device in accordance with another embodiment of the present patent application; and

FIGS. 7, 7A, 8, 8A and 9 show operational procedures of the exemplary electronic device of FIG. 6 in accordance with an embodiment of the present patent application.

### DETAILED DESCRIPTION OF THE DRAWINGS

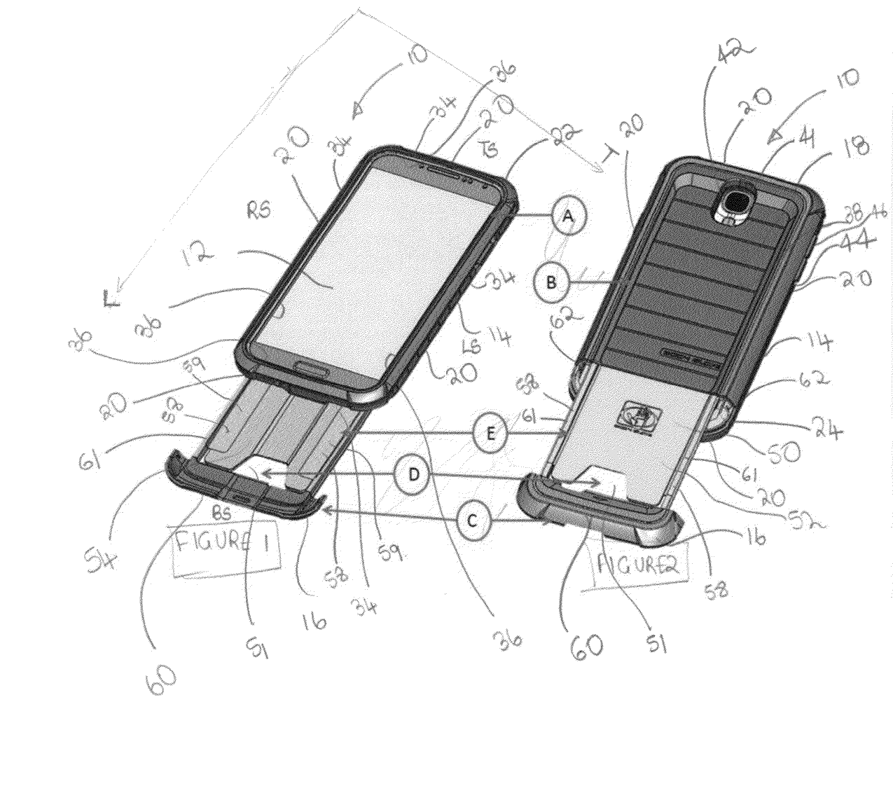

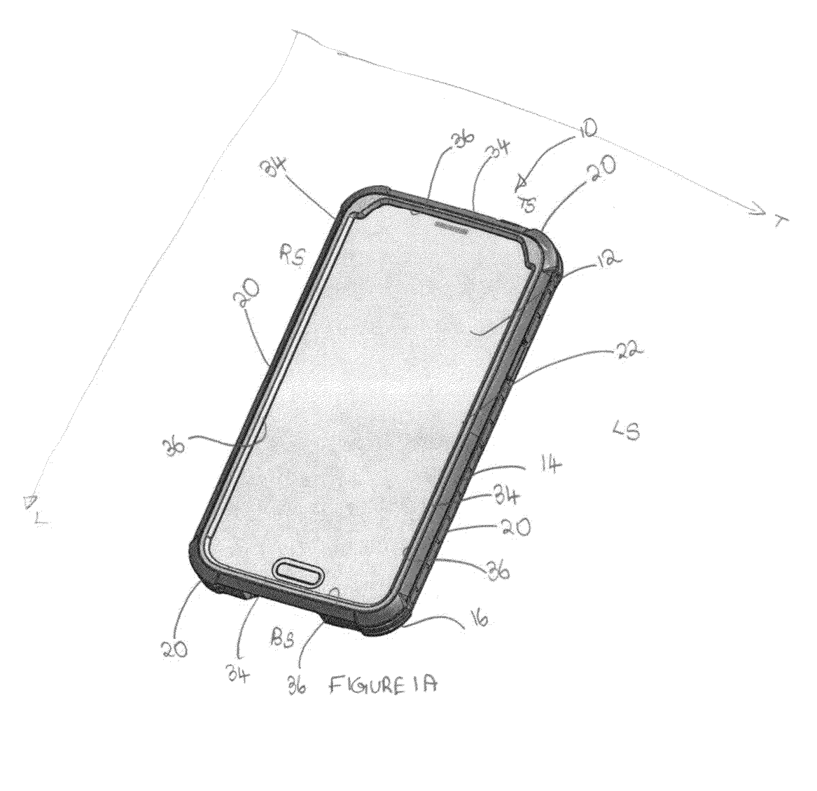

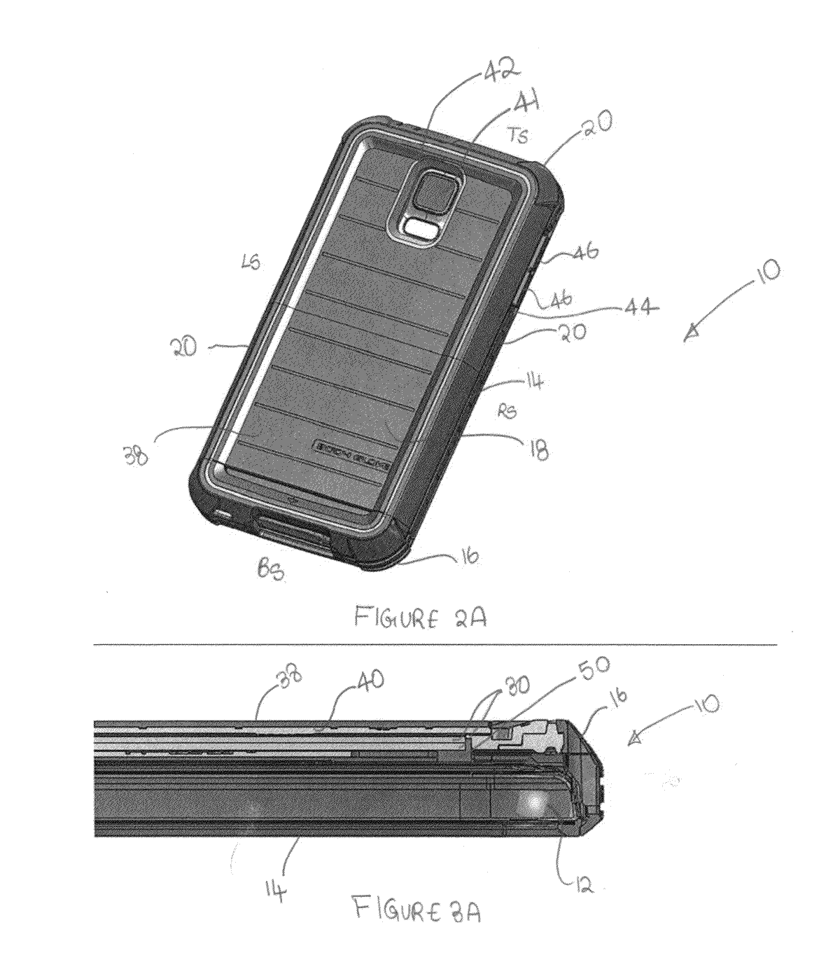

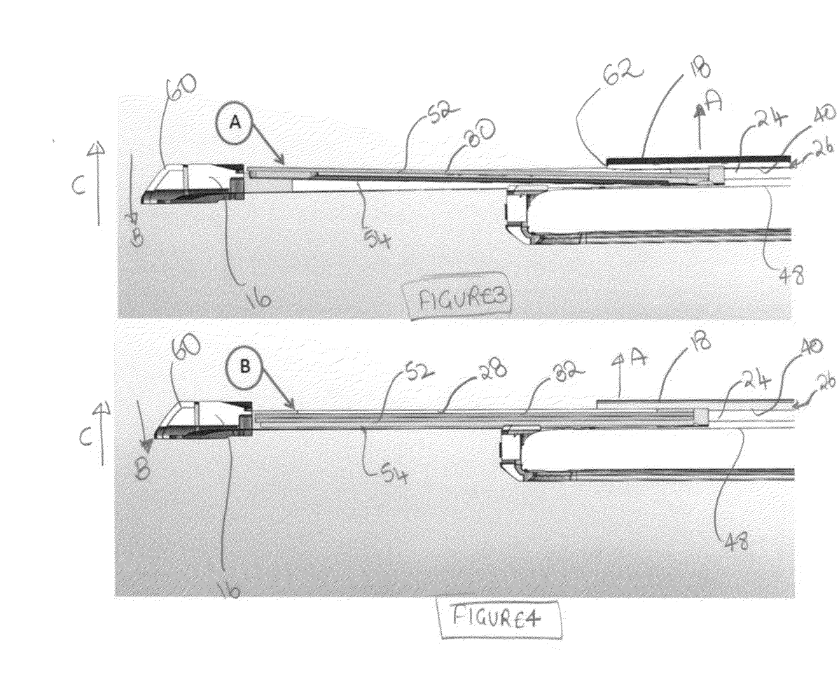

Referring to FIGS. 1, 1A, 2, and 2A, the present patent application provides a case 10 for use with an electronic device 12. The case 10 includes a case body 14 and a moveable member 16. The case body 14 has a back wall 18 and side walls 20 extending therefrom forming an opening or a receiving space 22 for receiving the electronic device 12. The case body includes a cavity 24 (as shown in FIGS. 3 and 4) provided in a rear portion 26 (as shown in FIGS. 3 and 4) thereof. The moveable member 16 is moveably connected to the case body 14 and received in the cavity 24. The moveable member 16 is moveable between (i) a first position (as shown in FIGS. 1A, 2A, and 3A) stored in the cavity 24 and (ii) a second position (as shown in FIGS. 1-4) withdrawn from the cavity 24 to present one or more articles or items 30 (as shown in FIG. 3) to a user tier removal.

The electronic device 12 is a portable electronic device such as, but are not limited to, a cellular phone, a PDA, a music player (e.g., MP3 player), a tablet, a gaming device, and the like. The electronic device 12 has a screen for displaying or viewing.

The one or more articles or items 30 may include, but are not limited to, debit or credit card(s), identification card(s) (e.g., license), or other similar cards (e.g., rewards, patient, citizenship, or membership cards), folded papers or documents, money bills/currency, keys, personal or bank checks, makeup, jewelry, and/or hygiene products. Besides personal items, items or articles held by the case 10 may also include devices that may be used with the electronic device 12, such as an earpiece (e.g., Bluetooth® enabled), ear buds, computer chips, memory cards, and the like.

The case 10 is a detachable device and allows for a dual functionality in that a user may use the case 10 to carry the electronic device 12 and to carry one or more personal items 30, 32. The case 10 also protects the electronic device 12 from shocks, impacts or scratches, for example. The case 10 may be held by the user in any number of planes. Generally, the disclosed design of case 10 is slim and there is little to no additional bulk or weight added to the case 10. The case body 14 is shaped and constructed in such a manner that their edge/corner portions are rounded to provide a comfortable grip to users. In other embodiments, the edge/corner portions of the case body 14 may be rectangular. The case 10 may generally be formed using processes such as an injection molding process. The case 10 may be made from an injection-molded plastic material.

One or more side walls 20 of the case body 14 may comprise one or more edges 34. In some embodiments, the edge(s) 34 of one or more side walls 20 comprises a lip 36 for removably grasping a front of the electronic device 12 when the electronic device 12 is inserted therein. The case 10 may optionally comprise a front member configured to releasably lock with the case body 14 to encapsulate the electronic device 12 therein. For example, the front member comprises at least a peripheral wall with one or more openings. For example, the one or more openings may enable viewing of the screen of the electronic device 12 and may enable access to one or more keys or buttons of the electronic device 12. The edges of side walls of the front member may be configured to releasably lock (e.g., using female and male connection members) with the edges of side walls 20 of the case body 14 to surround and capture the electronic device 12 within the case 10.

The one or more side walls 20 and their edges 34 may be referred to as the front frame of the case 10 and may be formed from a polycarbonate (PC) material. The case back wall 18 may be formed from a Polycarbonate (PC) material overmolded with a Thermoplastic polyurethane (TPU) material. The moveable member 16 may be formed from a Polycarbonate (PC) material and a Silicone material overmolded with a Thermoplastic polyurethane (TPU) material. The moveable member 16 may be formed from an Acrylonitrile Butadiene Styrene (ABS) material, a combination of PC and ABS materials, or other hard plastic materials that would be appreciated by one skilled in the art. In such an embodiment, the moveable member 16 may be overmolded with a Silicone material, a Thermoplastic Polyethylene (TPE) material, a Thermoplastic Olefin (TPO) material, a Polyurethane (PU) material or other elastomeric materials that would be appreciated by one skilled in the art.

The case 10 may have one or more openings 42 and 44 (e.g., in one or more of the side walls 20 and/or the back wall 18) that correspond to features of the electronic device 12. For example, an electronic device may have a camera associated therewith and the opening(s) 42 in the case back wall 18 may correspond to a placement of a lens and/or flash device 41 of the associated camera. An electronic device may have button(s) or key(s) 46 for operation of the electronic device, slot(s) for providing memory or other functions not built into the electronic device, and/or port(s) for electrical connections and/or for audio waves to pass through on the sides of the electronic device. In some embodiments, the opening(s) 44 in the case 10 may correspond to a placement of such button(s), key(s), slot(s), or port(s).

The back wall 18 has a back or an outer surface 38 and a front or an (inside or) inner surface 40 (as shown in FIGS. 3 and 4). The electronic device 12 may be inserted into the case body 14 such that its back is positioned adjacent and parallel to the inner surface 40 of the back wall 18 of the case body 14 and its sides are positioned adjacent or against inner surface(s) of the one or more side walls 20 of the case body 14. The electronic device 12 may be secured within the receiving opening 22 of the case body 14 via, for example, a friction-fit arrangement, a snap-fit arrangement, or any similar securing arrangement as would appreciated by one skilled in the art. The edge(s) of the side walls 20 of the case body 14 may assist in retaining the electronic device 12 in the case 10. Dimensions of the one or more side walls 20 and/or the back wall 18 may vary according to the type of electronic device 12 to be held in the case 10.

The case body 14 may include an electronic device support member 48 (as shown in FIGS. 3 and 4) that is configured to support the electronic device 12 when the electronic device 12 is received in the receiving space 22. The case body 14 defines the cavity 24 which may be shaped as a slot, below the electronic device support member 48.

The moveable member 16 is configured to be moveable between (i) the first position stored in the cavity 24 (as shown in FIGS. 1A, 2A and 3A) and (ii) the second position (as shown in FIGS. 1-4) withdrawn from the cavity 24 to present one or more articles or items 30 to a user for removal. The moveable member 16 may form a trailing end 60 that seals against portions 62 of the case body 14 when the moveable member 16 is in the first position (i.e., fully inserted within the case body 14).

The moveable member 16 is moveably or slideably connected to the case body 14 and is received in the cavity 24. The moveable member 16 is operatively connected to a structure of the case body 14 through a complementary track system located on the moveable member 16 and on the case body 14. The complementary track system is configured such that the moveable member 16 is selectively slideable in and out of the cavity 24 in the case body 14. The track system may include a guide structure formed in two opposing rear, inner side walls of the case body 14, where the moveable member 16 includes stop/tab members formed on two opposing outer side walls thereof and fitting in the guide structure to permit the moveable member 16 move/slide in and out of the case body 14. When the moveable member 16 is completely pulled out of the cavity 24 to allow for access to articles/items on the moveable member 16, the stop members are stopped by portions the guide structure, preventing the moveable member 16 from falling out of or from being separated from the case body 14.

The track system may be configured to permit a generally linear movement of the moveable member 16 in and out of the cavity 24. For example, the movement of the moveable member 16 is substantially restricted to linear translation forward and rearward with respect to the case body 14, and in and out of the cavity 24. Although the moveable member 16 is shown to be moveable between the first and second positions in a longitudinal direction L of the case 10, it is appreciated that the moveable member 16 may be configured to be moveable between the first and second positions in a transverse direction T (opposite to the longitudinal direction L) of the case 10. That is, the moveable member 16 may be configured to slid open towards left side LS of the case 10 or slide open towards right side RS of the case 10. Also, the moveable member 16 may be configured to slide open towards top side TS (instead of bottom side BS, as shown in the illustrated embodiment) of the case 10. The moveable member 16 may be configured to snap onto the back of the case 10 and then open and close in any of the above configurations (rotationally, or left, right, up or down). The moveable member 16 may also be configured such that it is opened using a pivoting mechanism to either side (i.e., right side RS or left side LS) of the case 10 so as to have a “pendulum” like movement.

The moveable member 16 may include an article supporting member 50 having a first surface 52 and a second surface 54 opposite the first surface 52. One of the first surface 52 and second surface 54 may be a forward surface and the other of the first surface 52 and second surface 54 may be a rearward surface. The first surface 52 and second surface 54 are substantially planar surfaces and are configured for receiving one or more articles or items thereon. The moveable member 16 may be used from both sides such that one or more articles or items may be received on either the first surface 52 or the second surface 54.

The article supporting member 50 may include one or more openings. For example, the article supporting member 50 may include an opening that corresponds to a placement of a lens and/or flash device 41 of a camera associated with the electronic device, when the moveable member 16 is in the first position. This opening is configured to prevent the blockage the lens and/or flash device of the associated camera when the moveable member 16 is in the first position and is stored in the cavity 24.

The moveable member 16 may also include a peripheral wall surrounding edge portions of the article supporting member 50. The peripheral wall is configured to provide article containment by preventing articles from falling from the moveable member 16 especially when the moveable member 16 is in the second position. The portions of the track system disposed on the moveable member 16 may serve as the peripheral wall along the longitudinal direction L (as shown in FIG. 1).

The moveable member 16 may include a lock to prevent the moveable member 16 from opening for rugged conditions or security issues. That is, the moveable member 16, when in the first position, is selectively locked within the cavity 24 of the case body 14 by a lock or lock mechanism. The lock mechanism may include a first member coupled to the case body 14 and a second member coupled to the moveable member 16.

The lock may include a powered lock that may be opened or unlocked by using the power from the battery of the electronic device 12. The lock may include a mechanical lock (i.e., not powered) that may be a tab or other member that the user may turn (rotationally) to lock the moveable member 16. The lock may include a magnetically operated lock.

The lock may include any of the locks discussed above that may be controlled using an application on the electronic device 12 for the security of the electronic device 12 itself using a “sleep-wake” feature. For example, the lock may be configured to engage when the electronic device 12 is put to sleep or when the electronic device 12 is manually locked, and the lock may be configured to unlocked/disengage when the electronic device 12 is in wake mode or when the user inputs the pin number or fingerprint.

The lock may also include a manual combination lock similar to those found on travel luggage. The lock may include a hook and loop fastener type locking device/mechanism. The lock may have a flap or cover either in the case or the lock itself so as to cover the lock from being exposed.

The case 10 may include an additional security feature, such as, a proximity alarm configured to generate a noise, sound or an audible signal when the moveable member 16 is left open, not locked, being tampered with or the moveable member 16 has not been opened in a certain period of time.

Referring to FIGS. 3 and 4, the moveable member 16 and the rear portion 26 of the case body 14 are configured to furan a storage space 28 therebetween to receive the one or more articles or items 30. At least one of the moveable member 16 and the rear portion 26 of the case body 14 is configured to be flexible to increase the storage space 28 therebetween. That is, in one embodiment, only the moveable member 16 is configured to be flexible to increase the storage space 28 therebetween, while, in another embodiment, only the rear portion 26 of the case body 14 is configured to be flexible to increase the storage space 28 therebetween. In yet another embodiment, both the moveable member 16 and the rear portion 26 of the case body 14 are both configured to be flexible to increase the storage space 28 therebetween. The at least one of the moveable member 16 and the rear portion 26 of the case body 14 is configured to deform to increase the storage space 28 therebetween.

At least a member 58 (as shown in FIGS. 1 and 2) operatively associated with the moveable member 16 is configured to be flexible to enable the moveable member 16 to deform in a first direction B (as shown in FIGS. 3 and 4) to receive one or more new articles or items 32 on the surface 52 of the moveable member 16. The first direction may be a direction as shown by arrow B extending from the surface 52 to surface 54 of the moveable member 16.

The flexible member 58 of the moveable member 16 is a flexible membrane 58. The moveable member 16 may include two flexible membranes 58 molded on either side of the article supporting member 50 that allow the article supporting member 50 to flex to capture more than one card or accessory at one time (FIGS. 3 and 4). With the flexible moveable member design, the slim profile of the case is kept consistent, even when cards are inserted within.

The flexible member 58 may include a first portion 59 connected to portions of the article supporting member 50 and a second portion 61 connected to portions of the track system of the moveable member 16. The first portion 59, the second portion 61, and/or both may be configured to be flexible. The first portion 59 may be connected to the surface 54 of the moveable member 16 or may be connected to the surface 52 of the moveable member 16.

The rear portion 26 of the case body 14 may include its back wall 18 and/or rear portions of its side wails 20. In one embodiment, flexible attributes are designed within the perimeter of the case back wall 18 by overmolding a flexible material within, this allows the case back wall 18 of the case body 14 to flex outward in the direction of the arrow A (as shown in FIGS. 3 and 4), expanding the storage space 28 that holds the cards and items.

The moveable member 16 and the rear portion 26 of the case body 14 may be configured to deform in opposite directions to increase the storage space 28. For example, the moveable member 16 is configured to deform in the direction of the arrow B (as shown in FIGS. 3 and 4) and the rear portion 26 of the case body 14 is configured to deform in the direction of the arrow A (as shown in FIGS. 3 and 4).

The two flexible membranes 58 molded on either side of the article supporting member 50 may be removed, and the article supporting member 50 may be molded to be stationary within the moveable member 16 to allow no movement. In this embodiment, flexible attributes designed within the perimeter of the case back wall 18 allow the case back wall 18 of the case body 14 to flex outward in the direction of the arrow A (as shown in FIGS. 3 and 4), expanding the storage space 28 that holds the cards and items.

The two flexible membranes 58 molded on either side of the article supporting member 50 and the flexible attributes designed within the perimeter of the case back wall 18 may be combined in one design to allow maximum space to store items or articles.

The article supporting member 50 and a peripheral wall of the moveable member 16 may define a compartment for receiving one or more articles or items therein. The flexible membrane(s) 58 operatively associated with the moveable member 16 are configured to flexible to enable the moveable member 16 move/deform within the cavity 28 so as to increase the size of the compartment so that one or more new articles can be received in the compartment.

The moveable member 16 may be configured to flex in the opposite directions such that moveable member 16 may be used from both sides.

For example, the compartment for receiving one or more articles or items may be formed on the surface 52 of the article supporting member 50 with the flexible membrane(s) 58 operatively connected to portions of the surface 54 of the article supporting member 50 such that the moveable member 16 moves/deforms in the direction of the arrow B within the cavity 28 so as to increase the size of the compartment formed with the surface 52 of the article supporting member 50. The flexible attributes of the rear portion 26 of the case body 14 enable the rear portion 26 of the case body to deform in a second direction as shown by arrow A (in FIGS. 3 and 4) opposite to the first direction as shown by arrow B (in FIGS. 3 and 4) so as to receive one or more new articles or items 32 on the surface 52 of the moveable member 16.

The compartment may also be formed on the surface 54 of the article supporting member 50 with the flexible membrane(s) 58 operatively connected to portions of the surface 52 of the article supporting member 50 such that the moveable member 16 moves/deforms in the direction of the arrow C within the cavity 28 so as to increase the size of the compartment formed with the surface 54 of the article supporting member 50. The flexible member 58 operatively associated with the moveable member 16 may be configured to enable the moveable member 16 to deform in a first direction C to receive one or more new articles or items 32 on the surface 54 of the moveable member 16. The first direction may be a direction as shown by arrow C extending from the surface 54 to surface 52 of the moveable member 16. The flexible attributes of the rear portion 26 of the case body 14 enable the rear portion 26 of the case body 14 to deform in the first direction as shown by arrow A (in FIGS. 3 and 4) along with the moveable member 16 (deforming in direction C as shown in FIGS. 3 and 4) so as to receive one or more new articles or items on the surface 54 of the moveable member 16. That is, in this embodiment, both the rear portion 26 of the case body 14 and the moveable member 16 are configured to deform in the same direction so as to receive one or more new articles or items on the surface 54 of the moveable member 16.

The moveable member or drawer 16 is constructed and arranged to capture, contain and allow easy access to articles or items. The flexible membrane 58 of the moveable member or drawer 16 allows the compartment that holds the cards to expand so additional cards and items can be placed in the drawer, while containing everything securely within. The compartment that holds cards and other items is accessible by pulling the drawer downwards. In the above-discussed embodiments, a very slim profile to the case is kept when no cards or items are stored within the case.

In one embodiment, the back wall 18 of the case 10 may be designed such that the case 10 “pops” outward to create a storage compartment without even having any articles or items within the case 10. This design allows the case 10 to be in the shape of a pocket and articles or items may be thrown in loosely.

The back wall 18 of the case 10 may include a clear or opaque viewing window that allows the user to view the articles or items stored within the locked moveable member 16 without having to unlock the moveable member 16. For example, the clear or opaque viewing window allows the user to scan articles or items having barcodes through the case 10 without opening or unlocking the moveable member 16. The clear or opaque viewing window may be used to add an area where a name, address or other contact information could be displayed. Also, the clear or opaque viewing window may be used to display driver license stored within the locked moveable member 16 without having to unlock the moveable member 16.

The moveable member 16 may be configured to include a cord management feature that may be built into the moveable member 16 or may include a custom cord receiving member that may be placed within the moveable member 16. For example, the cord management feature may be useful when carrying common cord accessories, such as, for example, ear buds, charging cords, etc. that many users carry with their electronic devices.

The moveable member 16 may be configured to include a battery storage area that may store additional batteries to charge the electronic device or power security features, such as the lock feature and the alarm (proximity) security feature described in the patent application.

The moveable member 16 configured to hold the cards or similar items may be configured to be interchangeable with custom molded trays that are configured to accept other items more efficiently, such as keys, makeup, jewelry, hygiene products, or a clip for money and other notes.

The moveable member 16 may be configured to use a magnet to repel the moveable member 16 open or closed. For example, a pair of magnetic assemblies may be positioned on guide rails of the moveable member 16 and the case body 14. The pair of magnetic assemblies may include magnetic members. Some of magnetic members on one of the guide rails are configured to attract corresponding magnet members on other of the guide rails and some of the magnetic members on one of the guide rails are configured to repel corresponding magnet members on other of the guide rails. The attraction and repulsion of the magnetic members allow the moveable member 16 to automatically move to open or closed positions.

This magnetic member arrangement and/or additional magnetic member arrangement may be used as a security feature to lock the moveable member 16. The magnetic members may be activated and deactivated by a mechanical switch, or through an application on the electronic device 12. Radio Frequency Identification Device (RFID) or Bluetooth® technology may be used to assist or control with the locking/unlocking of the magnetic members.

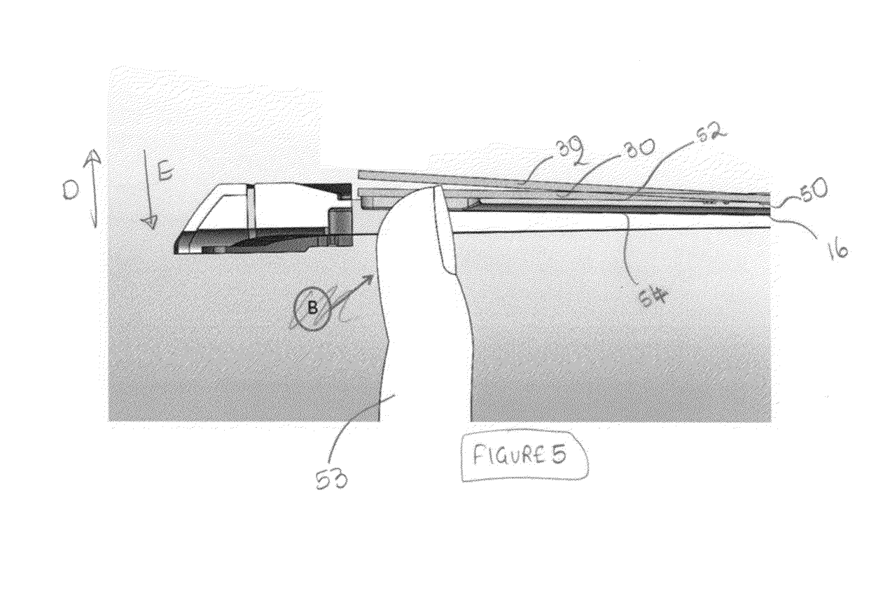

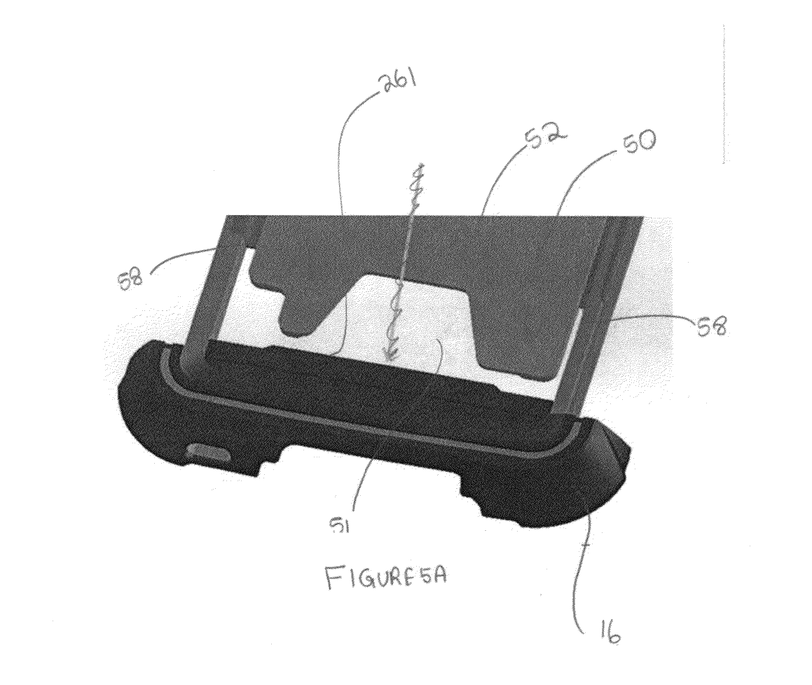

Referring to FIG. 5, the case 10 includes a through-hole design that allows a user finger or other object to push the stored cards upward or forward to remove the cards. This feature may become useful when more than one card is inserted within the case 10. For example, the article supporting member 50 of the moveable member 16 may include an opening 51 (as shown in FIGS. 1 and 2). The cards stored on either the surface 52 or 54 of the moveable member 16 may cover the opening 51.

The opening 51 allows a user finger 53 or other object to pass therethrough to push the cards 30, 32 stored on the surface 52 of the moveable member 16 in the direction of the arrow D to remove the cards from the case 10, for example, when the moveable member 16 is in the second position. The opening 51 also allows the user finger 53 or other object to pass therethrough to push the cards 30, 32 stored on the surface 54 of the moveable member 16 in the direction of the arrow E (opposite to the direction D) to remove the cards from the case 10 when the moveable member 16 is in the second position.

As shown in FIG. 5A, the moveable member 16 may include a flexible member 261 provided thereon. The flexible member 261 is configured to hold the articles/items in place in the moveable member 16. That is, the flexible member 261 is configured to snugly keep the articles/items behind or under it. The user/consumer may push the articles/items (e.g., cards) past the flexible member 261 so that the articles/items are caught by flexible member 261 and are held in place in the moveable member 16. Thus, the flexible member 261 is configured to prevent the articles/items from being caught inside the case when the moveable member 16 is opened and is configured to hold the articles/items down in place in the moveable member 16 when the moveable member 16 is in a closed position. The flexible member 261 is configured to keep the articles/items secure when the moveable member 16 moves to an open position so that the articles/items do not unintentionally fallout from the moveable member 16.

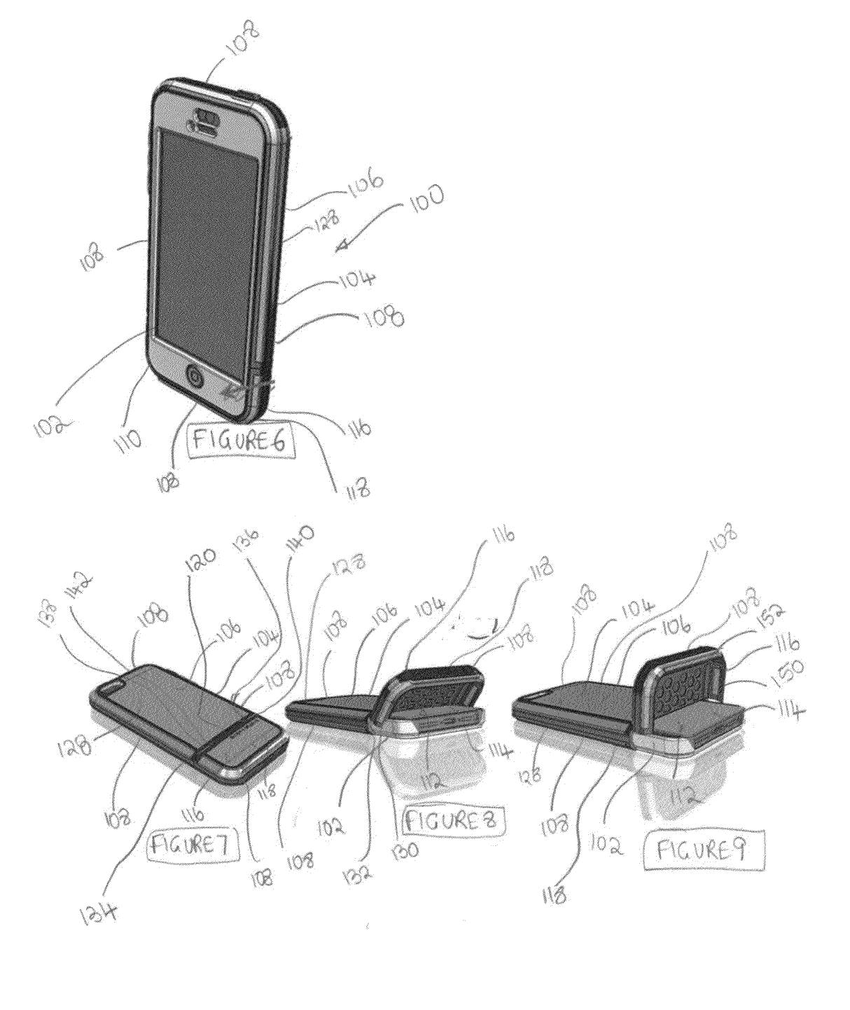

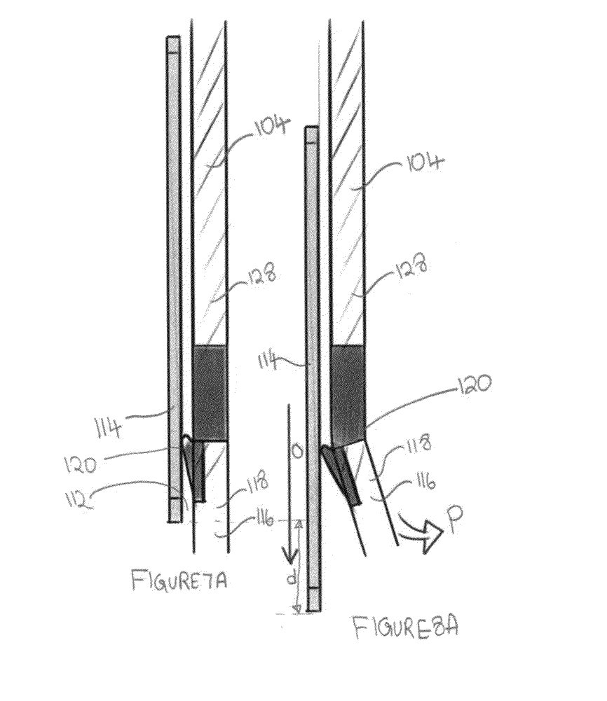

FIG. 6 shows a front, perspective view of an exemplary case 100 for use with an electronic device 102 and FIGS. 7-9 show operational procedures of the case 100 in accordance with another embodiment of the present patent application.

Referring to FIGS. 6-9, the case 100 includes a case body 104 having a back wall 106 and side walls 108 extending therefrom forming an opening or a receiving space 110 for receiving the electronic device 102. The case body 104 has a storage space 112 provided in a rear portion thereof for storing one or more articles or items 114 therein. The case 100 includes an actuator 116 that is operatively associated with the case body 104. The movement of the actuator 116 from a first position (as shown in FIG. 7) to a second position (as shown in FIG. 9) presents the stored articles or items 114, externally of the case body 104, so as to enable the user to remove the articles or items 114. The case body 104 described in this embodiment is similar to the embodiments previously described, except for the differences as will be noted below.

Edges on the one or more side walls 108 of the case body 104 may be configured to removably grasp the electronic device 102 when the electronic device 102 is inserted into the opening 110. The edges and the one or more side walls 108 of the case body 104 may be referred to a front frame. The front frame may be formed from a polycarbonate (PC) material, a Thermoplastic polyurethane (TPU) material or may be overmolded from the polycarbonate (PC) material and the Thermoplastic polyurethane (TPU) material. The case body back wall 106 may be formed from a polycarbonate (PC) material, a Thermoplastic polyurethane (TPU) material or may be overmolded from the polycarbonate (PC) material and the Thermoplastic polyurethane (TPU) material. The moveable member 16 may be formed from an Acrylonitrile Butadiene Styrene (ABS) material, a combination of PC and ABS materials, or other hard plastic materials that would be appreciated by one skilled in the art. In such an embodiment, the moveable member 16 may be overmolded with a Silicone material, a Thermoplastic Polyethylene (TPE) material, a Thermoplastic Olefin (TPO) material, a Polyurethane (PU) material or other elastomeric materials that would be appreciated by one skilled in the art.

The case body 104 may optionally include a support member that is operatively connected to the inner, side walls 108 of the case body 104 and configured to receive the electronic device 102 on a first surface thereon and one or more articles or items 114 on a second surface thereon. The support member may form a rearward surface for the storage space 112.

The actuator 116 may take several different forms. In the illustrated embodiment, the actuator 116 includes a portion 118 of the case body 104. That is, the case body 104 may include a stationary portion 128 and a moveable/pivotable portion 118. The moveable/pivotable portion 118 and the stationary portion 128 have adjacent edge portions 130 and 132 that extend across a width of the case. The edge portions 130 and 132 are secured to each other at opposite ends 136 and 138 and are otherwise unsecured to each other. The edge portions 130 and 132 are secured or connected to each other using separate living/flexible hinge portions 140 and 142, as would be appreciated by one skilled in the art.

The portion 118 of the case body 104 includes an integrally molded engagement member 120 positioned centrally on the edge portion of the moveable/pivotable portion 118 between the separate living/flexible hinge portions. The integrally molded engagement member 120 provides a “spatula” effect, pushing the cards outward, or out of the device case for removal. This design allows the articles or items stored in the storage space 112 to be easily grabbed with user's fingers as the stored articles or items extend past the edge of the electronic device 102.

The actuator 116 may be manually movable from the first position (as shown in FIGS. 7 and 7A) progressively toward the second position (as shown in FIG. 9). FIGS. 8 and 8A show intermediate positions of the actuator 116 that are between the first and the second positions. The actuator 116 may be constructed and arranged to be pivotably movable from the first position (as shown in FIGS. 7 and 7A) progressively toward the second position (as shown in FIG. 9).

The actuator 116 may optionally include a lock that is may be moveable between a lock position and an unlock position, wherein the movement of the lock from the lock position to the unlock position unlocks the actuator 116 to enable. movement of the actuator 116. As shown in FIGS. 7 and 7A, the actuator 116 is in the first position, wherein the actuator 116 is locked and is disposed coveringly over the storage space 112. The lock may include a latch member configured to engage with portion(s) of the actuator 116 to lock the actuator 116 in the first position. The lock may include a button that may be manually depressed so that lock is movable between the lock position and the unlock position. The lock feature may include any of the lock features described above with respect to the moveable member 16.

The actuator 116 may be configured such that it automatically “pops” open to the first intermediate position (as shown in FIG. 8) when the lock is released or unlocked. The user may then manually pivot the actuator 116 from the first intermediate position to the second intermediate portion (as shown in FIG. 8A) during which the integrally molded engagement member 120 engages with the article or item 114 and provides a “spatula” effect, pushing the article or item 114 by a distance d in the direction O. The actuator 116 is then pivoted in the direction of arrow P from the second intermediate portion (as shown in FIG. 8A) to the second position (as shown in FIG. 9) during which the integrally molded engagement member 120 continues to provide the “spatula” effect, pushing the cards further outward, or out of the device case for removal.

In another embodiment, the user may manually pivot the actuator 116 from the first position to the second position during which the integrally molded engagement member 120 provides a “spatula” effect, pushing the cards outward, or out of the device case for removal.

An inner surface 152 of the case body back wall 106 may include a knurled/rough surface pattern 130 thereon for providing frictional interface between the stored articles/items and the case body back wall 106 and for preventing the movement of the articles or items stored in the storage space 112 The inner surface 152 with the knurled/rough surface pattern 130 thereon may also be used for shock absorption.

The foregoing illustrated embodiments have been provided to illustrate the structural and functional principles of the present invention and are not intended to be limiting. To the contrary, the present invention is intended to encompass all modifications, alterations and substitutions within the spirit and scope of the appended claims.

What is claimed is:

1. A case for use with an electronic device, the case comprising:
a case body having a back wall and side walls extending therefrom forming an opening for receiving the electronic device, the case body having a cavity provided in a rear portion thereof; and
a moveable member moveably connected to the case body and received in the cavity,
wherein the moveable member and the rear portion of the case body are configured to form a storage space therebetween to receive one or more articles or items,
wherein the moveable member is moveable between (i) a first position stored in the cavity and (ii) a second position withdrawn from the cavity to present the one or more articles or items to a user for removal, and
wherein at least one of the moveable member and the rear portion of the case body is configured to be flexible to increase the storage space and to receive one or more new articles or items in the storage space.

2. The case of claim 1, wherein at least one of the moveable member and the rear portion of the case body is configured to deform to increase the storage space.

3. The case of claim 2, wherein the moveable member and the rear portion of the case body are configured to deform in opposite directions to increase the storage space.

4. A case for use with an electronic device, the case comprising:
a case body having a back wall and side walls extending therefrom forming an opening for receiving the electronic device, the case body having a cavity provided in a rear portion thereof; and
a moveable member moveably connected to the case body and received in the cavity, the moveable member configured to receive one or more articles or items on a surface thereof,
wherein the moveable member is moveable between (i) a first position stored in the cavity and (ii) a second position withdrawn from the cavity to present the one or more articles or items to a user for removal, and
wherein at least a member operatively associated with the moveable member is configured to be flexible to enable the moveable member to deform in a first direction to receive one or more new articles or items on the surface of the moveable member.

5. The case of claim 4, wherein at least a member operatively associated with the moveable member is a flexible membrane.

6. The case of claim 5, wherein the flexible membrane is molded on sides of the moveable member.

7. The case of claim 4, wherein the rear portion of the case body is configured to be flexible to enable the rear portion of the case body to deform in a second direction opposite to the first direction so as to receive one or more new articles or items on the surface of the moveable member.

8. The case of claim 4, wherein the rear portion of the case body is configured to be flexible to enable the rear portion of the case body to deform in the first direction along with the moveable member so as to receive one or more new articles or items on the surface of the moveable member.

9. The case of claim 4, wherein the surface of the moveable member is a forward surface or a rearward surface of the moveable member.

10. The case of claim 4, wherein the first direction is a forward direction or a rearward direction.

11. The case of claim 4, wherein the moveable member is slideably connected to the case body.

12. The case of claim 4, wherein the moveable member forms a trailing end that seals against portions of the case body when the moveable member is fully inserted within the case body.

13. The case of claim 4, wherein the moveable member, when in the first position, is selectively locked within the cavity of the case body by a lock mechanism.

14. A case for use with an electronic device, the case comprising:
a case body having a back wall and side walls extending therefrom forming an opening for receiving the electronic device;
the case body having a storage space provided in a rear portion thereof for storing one or more articles or items therein; and
an actuator operatively associated with the case body,
wherein movement of the actuator from a first position to a second position presents the stored articles or items, externally of the case body, so as to enable the user to remove the articles or items.

15. The case of claim 14, wherein the separated articles or items are presented to the user through a different opening than the one through which the electronic device is received.

16. The case of claim 14, wherein, when the actuator is in the first position, the one or more articles or items in the storage space are concealed by the case back wall to a person viewing the case.
